(19) United States
(12) Patent Application Publication
(10) Pub. No.: US 2003/0082838 A1
(43) Pub. Date: May 1, 2003

(54) Method and system for monitoring a semiconductor wafer plasma etch process

(76) Inventors: Joseph Petrucci, New Milford, CT (US); John Maltabes, Austin, TX (US); Karl Mautz, Round Rock, TX (US)

Correspondence Address: MOTOROLA INC, AUSTIN INTELLECTUAL PROPERTY, LAW SECTION, 7700 WEST PARMER LANE MD: TX32/PL02, AUSTIN, TX, 78729

(21) Appl. No.: 10/033,107

(22) Filed: Oct. 26, 2001

(51) Int. Cl. H01L 21/00; H01L 21/461

(52) U.S. Cl. 438/14; 156/345.25; 156/345.28; 438/7

(57) ABSTRACT

The present invention is related to a method of monitoring a semiconductor wafer (10) plasma etch process, comprising the steps of projecting light (12) on a wafer surface (14) during plasma etching, so that the light (12) is scattered by the wafer surface (14), detecting the scattered light (16), determining intensities of the detected light with dependence on at least one varying parameter, thereby creating a spectrum, and comparing the spectrum with stored data. The present invention further relates to a system for monitoring a semiconductor wafer plasma etch process.

### FIELD OF THE INVENTION

The present invention generally relates to a method of monitoring a semiconductor wafer plasma etch process, and more particularly to a method of in-situ monitoring. The present invention further relates to a system for monitoring a semiconductor wafer plasma etch process.

### BACKGROUND OF THE INVENTION

Etching in a plasma environment has several significant advantages when compared to wet etching. For example, plasmas are much easier to start and stop than simple immersion wet etching. Further, plasma etch processes are much less sensitive to small changes in the temperature of the wafer. These factors make plasma etching more repeatable than wet etching. For the etching of small features it is very important that plasma etches may have high anisotropies. Generally speaking, plasma etching produces structures with high quality and high reliability.

In order to achieve and to maintain such quality it is an important task to control the plasma etch processes. However, as a matter of fact, for plasma etch chambers processing wafers, typically the only measurement event that is occurring in real-time is the end-point determination. This is typically done using optical emission that looks for a depletion or rise in an emission wavelength of the etched species or byproduct, or by laser interferometry that measures the depth change in the film as it is etched away.

In order to improve the quality of etching results with high reliability, it is not sufficient to use only endpoint determination.

The present invention seeks to solve the above mentioned problems by providing a new method and a new system for monitoring a semiconductor wafer plasma etch process.

### BRIEF DESCRIPTION OF THE DRAWINGS

FIG. 1 is a schematic illustration of a scattering setup;

FIG. 2 is a diagram showing a reflectivity at different angles of incidence;

FIG. 3 is a diagram showing a reflectivity at different illumination wavelengths;

FIG. 4 is a diagram illustrating different process steps of a method according to the present invention; and

FIG. 5 is a diagram illustrating a system according to the present invention.

### DETAILED DESCRIPTION OF THE PREFERRED EMBODIMENTS

According to the present invention, a method of monitoring a semiconductor wafer plasma etch process is provided, comprising the steps of:

projecting light 12 on a wafer surface 14 during plasma etching, so that the light 12 is scattered by the wafer surface 14,

detecting the scattered light 16, determining intensities of the detected light with dependence on at least one varying parameter, thereby creating a spectrum, and

comparing the spectrum with stored data.

According to the present invention, there is further provided a system for monitoring a semiconductor wafer plasma etch process, comprising

means 18 for projecting light 12 on a wafer surface 14 during plasma etching, so that the light is scattered by the wafer surface 14,

means 20 for detecting the scattered light 16,

means 28 for determining intensities of the detected light with dependence on at least one varying parameter, thereby creating a spectrum, and

means 30 for comparing the spectrum with stored data.

On the basis of scatterometry techniques, it is possible to determine the etch profile in-line (in-situ). This is preferably accomplished by using completed wafers that have been manufactured by lithography and etching techniques. Starting from these wafers, the database of known and desired profiles can be built using scatterometry techniques, and the results can be used as a reference. The determination would be accomplished by measuring the linewidth or contact profile while plasma etching in real time. The linewidth features will be monitored using a scatterometry laser beam through a window of the etch chamber. The resultant image or data will be compared to the data base library of known and desired shapes for each process/film etch type. Alternatively, the reference data are based on a modeling of scatterometry.

An important advantage of the method and system according to the present invention is that during the etch, if the linewidth profile is not desirable, then a change in the etch process recipe parameters or an adjustment of the etch time can occur to modify the profile to the specification.

There are different types of scatterometry available. For example, the scatterometry may be performed at a fixed incidence angle and a fixed measuring angle using varying wavelength. Alternatively, an angle range can be measured with fixed wavelength.

Preferably, measures are taken to avoid problems of interfering wavelength and continuum levels associated with each plasma chemistry and process parameter recipe. Such measures can be the use of a curved window as an aspheric lens with enough distance to move to collector and change angles.

In a preferred embodiment, a HeNe laser, for example a red laser, can be used that has wavelengths that do not interfere with the plasma background or emission spectra. A mirror can be used to accomplish the beam angle change in combination with the optical lens window.

Also the use of two lasers at different wavelengths simultaneously could be used. These techniques can be used to collect a partial three dimensional image by combining the information from two wavelengths and the changing beam angle to provide improved resolution of the feature size and shape.

The optical probe parameters may be wavelengths, angle of incidence, polarization and/or azimuth angle.

A feedback loop and real time information processing can be performed to modify the etch process before or after endpoint, i.e. overetch, to modify and improve the feature profile shape prior to etch process completion.

FIG. 1 is a schematic illustration of a scattering setup. A semiconductor wafer 10 has a structured surface 14 that may be obtained by plasma etch processes. From a laser light source 18 light 12 is-projected-on the surface 14 at an angle of incidence Θᵢₙ, and it is reflected at a measuring angle Θₒᵤₜ. The scattered light 16 is measured by a detector 20. A quantity representing the intensity of the reflected light is the reflectivity R=Iₒᵤₜ/Iᵢₙ, i.e. the ratio of reflected intensity Iₒᵤₜ and incident intensity Iᵢₙ.

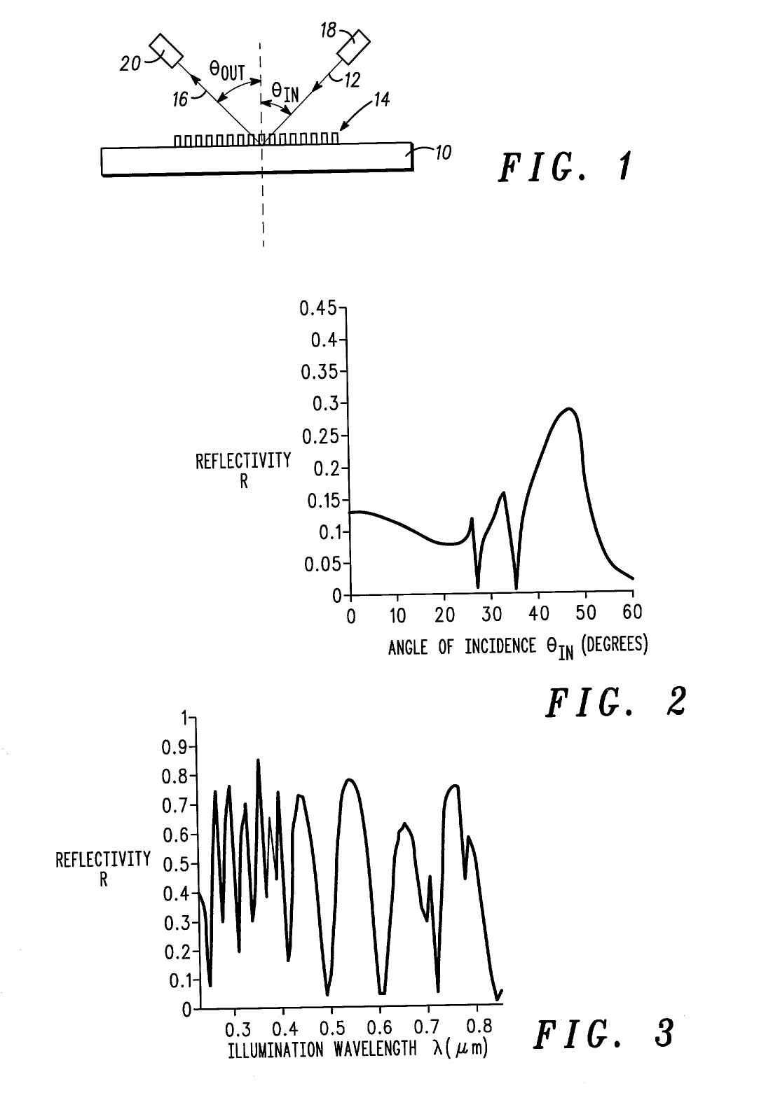

FIG. 2 shows a diagram illustrating the reflectivity R with dependence on the angle of incidence Θᵢₙ as an example. The reflectivity pattern shown in the diagram is dependent on the surface structure of the wafer.

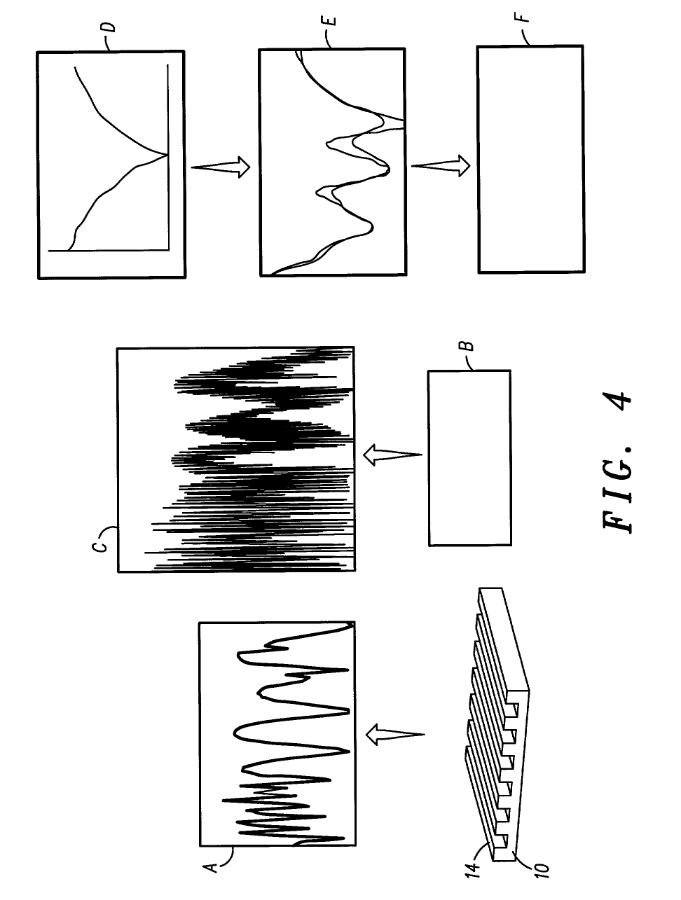

FIG. 3 shows a different diagram in which the reflectivity is illustrated with dependence on the illumination wavelength λ. Also in this case, the reflectivity pattern is dependent on the surface structure of the wafer.

FIG. 4 shows a diagram in order to illustrate a method according to the present invention. A wafer 10 with a structured surface 14 is monitored by scatterometry techniques. As a result, a spectrum A is generated. From a model of empirical data B further spectra C are generated that represent different structures. On the basis of the spectra A and C a comparison can by performed. This is done by calculating the degree of a fit D, determining the best match E, and providing the parameters of the best fit F.

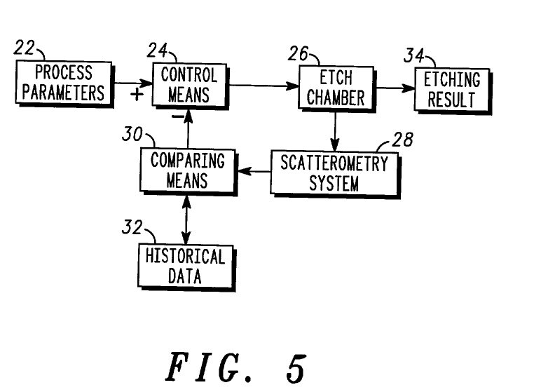

FIG. 5 is a diagram illustrating a system according to the present invention. Process parameters 22 are input into control means 24. These control means 24 influence the processes in the etch chamber 26. By a scatterometry system 28 the wafer surfaces inside the process chamber 26 can be evaluated. The resulting spectra are input into comparing means 30. Into the comparing means 30, there are also input historical data 32. On the basis of comparing, the control means 24 are influenced. As a result, semiconductor wafers 34 with the desired surface structure are produced.

While the invention has been described in terms of particular structures, devices and methods, those of skill in the art will understand based on the description herein that it is not limited merely to such examples and that the full scope of the invention is properly determined by the claims that follow.

1. A method of monitoring a semiconductor wafer plasma etch process, comprising the steps of:
projecting light on a wafer surface during plasma etching, so that the light is scattered by the wafer surface,
detecting the scattered light,
determining intensities of the detected light with dependence on at least one varying parameter, thereby creating a spectrum, and
comparing the spectrum with stored data.

2. The method according to claim 1, wherein the light is projected by at least one laser.

3. The method according to claim 1, wherein the semiconductor wafer plasma etch process is controlled with dependence on a result of the step of comparing.

4. The method according to claim 1, wherein the stored data are based on measured intensity spectra of desired surface structures.

5. The method according to claim 1, wherein the stored data are based on modelled intensity spectra of desired surface structures.

6. The method according to claim 1, wherein
a wavelength of the projected light is varied, and
intensities of the detected light are determined with dependence on the wavelength of the projected light.

7. The method according to claim 1, wherein
an angle of incidence of the projected light is varied, and
the intensities of the detected light are determined with dependence on the angle of incidence.

8. The method according to claim 1, wherein
a measuring angle is varied, and
the intensities of the detected light are determined with dependence on the measuring angle.

9. The method according to claim 1, wherein a wavelength of the projected light is selected with dependence on plasma inherent wavelengths.

10. The method according to claim 1, wherein the light is projected by two lasers with different wavelengths.

11. The method according to claim 1, wherein, if a linewidth profile of the created spectrum is not desirable, then a change in etch process recipe parameter is performed to modify the linewidth profile.

12. The method according to claim 1, wherein, if a linewidth profile of the created spectrum is not desirable, then an adjustment of an etch time is performed to modify the linewidth profile.

13. A system for monitoring a semiconductor wafer plasma etch process, comprising
means for projecting light on a wafer surface during plasma etching, so that the light is scattered by the wafer surface,
means for detecting the scattered light,
means for determining intensities of the detected light with dependence on at least one varying parameter, thereby creating a spectrum, and
means for comparing the spectrum with stored data.

14. The system according to claim 13, wherein the means of projecting the light comprise at least one laser.

15. The system according to claim 13, further comprising means for controlling the semiconductor wafer plasma etch process with dependence on a result of the step of comparing.

16. The system according to claim 13, wherein the stored data are based on measured intensity spectra of desired structures.

17. The system according to claim 13, wherein the stored data are based on modelled intensity spectra of desired surface structures.

18. The system according to claim 13, further comprising means for varying a wavelength of the projected light.

19. The system according to claim 13, further comprising means for varying an angle of incidence.

20. The system according to claim 13, further comprising means for varying a measuring angle.

21. The system according to claim 13, further comprising means for selecting a wavelength of the projected light with dependence on plasma inherent wavelengths.

22. The system according to claim 13, further comprising two lasers for projecting light with different wavelengths.

23. The system according to claim 13, wherein, if a linewidth profile of the created spectrum is not desirable, then a change in etch process recipe parameter is performed to modify the linewidth profile.

24. The system according to claim 13, wherein, if a linewidth profile of the created spectrum is not desirable, then an adjustment of an etch time is performed to modify the linewidth profile.
